(19) United States
(12) Patent Application Publication
(10) Pub. No.: US 2026/0357431 A1
(43) Pub. Date: Nov. 12, 2026

(54) HIGH-FLOW GAS GENERATOR AND SUPPLY METHOD FOR CHEMICAL VAPOR DEPOSITION EQUIPMENT

(71) Applicant: Hangzhou Atom Technology Co., Ltd., Hangzhou City (CN)

(72) Inventors: Yige ZHENG, Hangzhou City (CN); Borui WU, Hangzhou City (CN); Liqing JIANG, Hangzhou City (CN)

(21) Appl. No.: 19/661,823

(22) Filed: Apr. 29, 2026

Related U.S. Application Data
(63) Continuation of application No. PCT/CN2025/140349, filed on Dec. 5, 2025.

(30) Foreign Application Priority Data
May 8, 2025 (CN) 2025105904250

(51) Int. Cl. C23C 16/52; C23C 16/448; C23C 16/455

(52) U.S. Cl. CPC C23C 16/52; C23C 16/4485; C23C 16/45561

(57) ABSTRACT

The present disclosure discloses a high-flow gas generator and supply method for chemical vapor deposition equipment, and belongs to the technical field of semiconductor manufacturing. The present disclosure replaces a conventional flow meter with a butterfly valve for high-flow supply, and overcomes disadvantages of the flow meter including large resistance and small flow rate. Further, the generator integrates a vibration device and a heating device, and through control by coupling temperature and vibration, in combination with closed-loop pressure control, the high-flow gas generator is stabilized at target gas pressure, thereby maintaining gas supply at a stable flow rate. Furthermore, the present disclosure, through a mature PID algorithm and closed-loop gas pressure control, enables rapid arrival to a target flow rate (gas pressure), thereby achieving high-precision control, and unity of flow rate, precision, and stability.

### TECHNICAL FIELD

The present disclosure relates to a high-flow gas generator and supply method for chemical vapor deposition equipment, and belongs to the technical field of semiconductor manufacturing.

### BACKGROUND

Chemical vapor deposition (CVD) is a process for preparing thin-film materials for semiconductors and optoelectronic devices, while atomic layer deposition (ALD) is essentially a CVD process with higher precision in controlling film thickness and quality, and achieves precise control over film thickness and composition by alternately introducing different chemical vapor precursors onto a surface of a substrate and depositing a resulting material layer by layer on the substrate via chemical reactions, where the core lies in a self-limiting surface reaction mechanism, and only one atomic layer is deposited per reaction, thereby enabling generation of a very uniform and dense film.

Raw material supply is critical for both CVD and ALD processes, and stability, accuracy, and flow rate of raw material supply directly determine the quality of manufacturing materials. With continuous development of semiconductor materials and their penetration into all walks of life, requirements for quality of deposited films are increasingly stringent, but raw material supply, as a key factor affecting the quality of deposited films, has not received sufficient attention; and for example, an application of single-walled carbon nanotubes in battery slurries requires high-flow, highly stable, and high-precision gaseous carbon source supply to achieve high-quality growth of single-walled carbon nanotubes, and a current carbon source supply method is a conventional flow meter method.

Although a conventional method of flow control with a flow meter achieves high-precision control, inherent pipeline resistance (typically narrow pipelines of a high-precision flow meter result in pipeline resistance) causes failure to achieve high-flow gas supply and meet the needs of industrial-grade semiconductor material manufacturing; and other methods for high-flow supply cannot achieve high stability and precision in control, and therefore, prior art methods for gas supply at a flow rate fail to achieve the unity of flow rate, precision, and stability.

### SUMMARY

To further ensure deposition effects, the present disclosure provides a high-flow gas generator and supply method for chemical vapor deposition equipment, and is capable of achieving high-flow, highly stable, and high-precision gas supply for film deposition or atomic-scale material growth.

A high-flow gas supply method for chemical vapor deposition equipment, where the method is implemented based on a high-flow gas generator, and the high-flow gas generator includes: a source bottle, a heating device, an atomizer, a pressure gauge, and a controller; the source bottle is configured to store a gaseous source existing in a liquid state, the heating device and the atomizer are configured to convert the gaseous source in the source bottle from the liquid state to a gaseous state, and the controller is configured to adjust power of the heating device and the atomizer according to a required flow rate to adjust gas pressure in the source bottle; optionally, in the high-flow gas generator, the heating device is disposed outside the source bottle, the atomizer is disposed in the source bottle, an outlet of the source bottle is connected to the pressure gauge via a three-way valve, an angle valve is connected between the pressure gauge and the three-way valve, another port of the three-way valve is connected to a gas supply pipeline via a butterfly valve, and the gas supply pipeline is connected to a chemical vapor deposition chamber; the heating device, the atomizer, and the pressure gauge are all connected to the controller; the method includes:
S1: calibrating a relationship between pressure in the source bottle and a flow rate for the gaseous source existing in a liquid state in the source bottle; and
S2: determining target pressure in the source bottle according to a required flow rate, and using a PID algorithm to control power of the heating device and the atomizer to stabilize pressure in the source bottle at the target pressure.

Optionally, the S1 includes:
S1.1: placing the gaseous source existing in a liquid state into the source bottle, adjusting power of the heating device and the atomizer to stabilize gas pressure in the source bottle at A₁ kPa, evacuating the chemical vapor deposition chamber to vacuum, opening the butterfly valve to supply gas to the chemical vapor deposition chamber at a certain flow rate for N time, and measuring the gas pressure in the chemical vapor deposition chamber, where the gas pressure is denoted as B₁;
S1.2: calibrating gas pressure B₂ in the chemical vapor deposition chamber after supplying a calibration gas at a flow rate of Q_{calibration} for N time via a mass flow meter; and
S1.3: calculating an actual flow rate Q1 corresponding to gas supply to the chemical vapor deposition chamber for N time when the gas pressure in the source bottle is stabilized at A₁ kPa via the following flow rate conversion formula:

$$Q 1 = \frac{{B}_{1}}{{B}_{2}} \times \frac{{C}_{calibration}}{{C}_{gaseous source}} \times {Q}_{calibration}$$

where Q_{calibration} is a gas flow rate of the calibration gas and known; C_{gaseous source} is a mass flow conversion coefficient of the gaseous source existing in a liquid state stored in the source bottle; and C_{calibration} is a mass flow conversion coefficient of the calibration gas;
S1.4: repeating the above S1.1 to S1.3 to obtain an actual flow rate Q2 corresponding to gas supply to the chemical vapor deposition chamber for N time when the gas pressure in the source bottle is stabilized at A₂ kPa, A₂≠A₁;
S1.5: fitting and determining parameters α and β in an expression of relationship between gas pressure P in the source bottle and a flow rate Q according to the actual flow rates Q1 and Q2 corresponding to the gas pressures A₁ and A₂ obtained in the S1.3 and the S1.4:

Q=α×P+β
where P represents gas pressure in the source bottle, and Q is a gas flow rate corresponding to the gas pressure P in the source bottle.

Optionally, the method further includes before using a PID algorithm to control power of the heating device and the atomizer to stabilize pressure in the source bottle at the target pressure in the S2: determining a relationship between liquid-vapor conversion efficiency and coupling of temperature provided by the heating device and vibration power of the atomizer:
current power of the heating device is defined as follows: W_{heating}=T_{current}/2T_{vaporization}, where T_{current} represents current temperature of the generator, and T_{vaporization} represents vaporization temperature of liquid in the source bottle;
power of the atomizer is defined as W_{atomization}, and current power of the entire generator is denoted as: W=K₁*W_{heating}+K₂*W_{atomization},
it is known that 2W=W_{heating}+W_{atomization}, where K₁ and K₂ are power weight coefficients of the heating device and the atomizer, and corresponding pressure is obtained by adjusting the power W of the entire generator.

Optionally, K₁ and K₂ are determined by the following method:
heating the source bottle to temperature T₁ by using the heating device, where T₁>T_{vaporization}, and adjusting the power of the atomizer to half of maximum power, with the power denoted as W_{atomization1}; observing current gas pressure P₁ displayed by the pressure gauge after the gas pressure in the source bottle is stabilized;
heating the source bottle to temperature T₂ by adjusting the heating device while keeping the power of the atomizer unchanged, where T₂≤2 T_{vaporization}, and observing gas pressure displayed by the pressure gauge as P₂;
adjusting heating temperature back to T₁, adjusting the power of the atomizer to W_{atomization2} and W_{atomization2}≠W_{atomization1}, and observing gas pressure displayed by the pressure gauge as P₃;
accordingly:

$$\frac{{K}_{1}}{{K}_{2}} = \frac{( {P}_{2} - {P}_{1} ) * {T}_{1} * ( {W}_{a t o m i z a t i o n 2} - {W}_{a t o m i z a t i o n 1} )}{( {T}_{2} - {T}_{1} ) * ( {P}_{3} - {P}_{1} ) * {W}_{a t o m i z a t i o n 1}}$$

obtaining K₁ and K₂ by deriving:

$${K}_{1} = \frac{\frac{( {P}_{2} - {P}_{1} ) * {T}_{1} * ( {W}_{atomization 2} - {W}_{atomization 1} )}{( {T}_{2} - {T}_{1} ) * ( {P}_{3} - {P}_{1} ) * {W}_{atomization 1}}}{( 1 + \frac{( {P}_{2} - {P}_{1} ) * {T}_{1} ( {W}_{atomization 2} - {W}_{atomization 1} )}{( {T}_{2} - {T}_{1} ) * ( {P}_{3} - {P}_{1} ) * {W}_{atomization 1}} )}$$

$${K}_{2} = \frac{1}{( 1 + \frac{( {P}_{2} - {P}_{1} ) * {T}_{1} * ( {W}_{a t o m i z a t i o n 2} - {W}_{a t o m i z a t i o n 1} )}{( {T}_{2} - {T}_{1} ) * ( {P}_{3} - {P}_{I} ) * {W}_{a t o m i z a t i o n 1}} )}$$

the heating device is a heating jacket capable of temperature display, and power is automatically adjusted by adjusting temperature.

Optionally, the calibration gas in the S1.2 is an Ar/H₂ gas.

Optionally, A₁ ranges from 1 kPa to 3 kPa.

Optionally, the gaseous source existing in the liquid state includes ethanol, methanol, and phenol.

A second objective of the present disclosure is to provide a high-flow gas generator for chemical vapor deposition equipment, where the high-flow gas generator includes: a source bottle, a heating device, an atomizer, a pressure gauge, and a controller; the source bottle is configured to store a gaseous source existing in a liquid state, the heating device and the atomizer are configured to convert the gaseous source in the source bottle from the liquid state to a gaseous state, and the controller is configured to adjust power of the heating device and the atomizer according to a required flow rate to adjust gas pressure in the source bottle.

Optionally, in the high-flow gas generator, the heating device is disposed outside the source bottle, the atomizer is disposed in the source bottle, an outlet of the source bottle is connected to the pressure gauge via a three-way valve, an angle valve is connected between the pressure gauge and the three-way valve, another port of the three-way valve is connected to a gas supply pipeline via a butterfly valve, and the gas supply pipeline is connected to a chemical vapor deposition chamber; the heating device, the atomizer, and the pressure gauge are all connected to the controller.

Optionally, a material of the source bottle includes stainless steel, glass, ceramics, and Polytetrafluoroethylene (PTFE).

The present disclosure has the following beneficial effects:
1. High flow rate: The present disclosure replaces a conventional flow meter with a butterfly valve for high-flow supply, and overcomes disadvantages of the flow meter including large resistance and small flow rate. Additionally, the generator integrates a vibration device and the heating device to maximize the generation of a gaseous source.
2. High stability: While ensuring a high flow rate, the present disclosure achieves stable high-flow supply. In the present disclosure, through control by coupling temperature and vibration, in combination with closed-loop pressure control, the high-flow gas generator is stabilized at target gas pressure, thereby maintaining gas supply at a stable flow rate.
3. High precision: The present disclosure provides a gas generation control method capable of controlling liquid-vapor conversion efficiency through coupling of temperature and vibration power, and achieves higher-precision gas pressure control through coupling control. The present disclosure, through a mature PID algorithm and closed-loop gas pressure control, enables rapid arrival to a target flow rate through gas pressure control, thereby achieving high-precision control.

### BRIEF DESCRIPTION OF THE DRAWINGS

To describe the technical solutions in the embodiments of the present disclosure more clearly, the accompanying drawings required for describing the embodiments are briefly described below. Apparently, the accompanying drawings in the following description show merely some embodiments of the present disclosure, and those of ordinary skill in the art may still derive other drawings from these accompanying drawings without creative efforts.

FIG. 1 is a schematic structural view of a high-flow gas generator for chemical vapor deposition equipment provided in the present disclosure, where: 1—source bottle, 2—heating device, 3—atomizer, 4—three-way valve, 5—pressure gauge, 6—angle valve, 7—butterfly valve, and 8—gas supply pipeline.

FIG. 2 is a comparison diagram of growth of single-walled carbon nanotubes when gaseous sources of different flow rates are introduced for the growth of single-walled carbon nanotubes.

FIG. 3 is a flow rate comparison diagram of gas supply based on ethanol flow control through a conventional method of flow control with a flow meter and a high-flow gas generator provided in the present disclosure.

FIG. 4 is a flow rate diagram of gas supply based on ethanol flow control using a high-flow gas generator provided in the present disclosure.

FIG. 5 is a comparison diagram of Raman spectra of single-walled carbon nanotubes grown based on carbon source supply by a prior art Horiba flow meter and a high-flow gas generator provided in the present disclosure.

### DETAILED DESCRIPTIONS OF THE EMBODIMENTS

In order to make the objectives, technical solutions, and advantages of the present disclosure clearer, the embodiments of the present disclosure will be further described in detail below with reference to the accompanying drawings.

First, a conventional flow control method is introduced as follows:

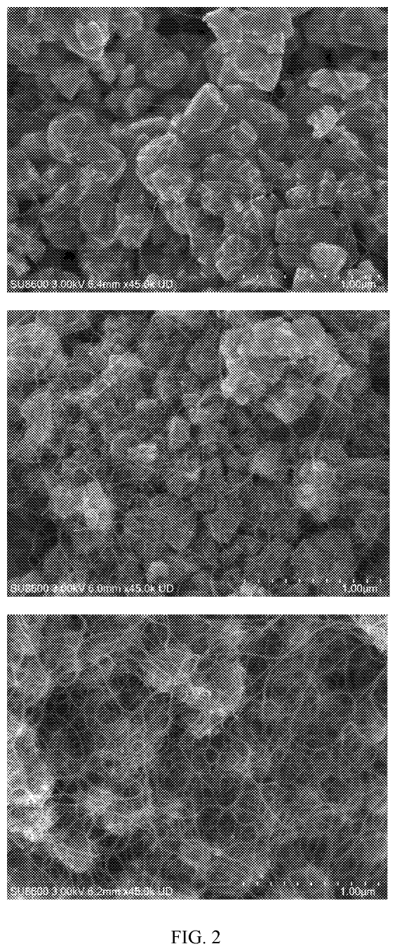

A prior art ethanol flow supply method: As a carbon source for atomic layer film deposition, ethanol is currently supplied by a flow tank and controlled by a flow meter in a flow rate, gas supply at the flow rate is achieved by self-evaporation of ethanol, and flow control is achieved by setting flow meter parameters. In practical use, this control method has two major disadvantages: first, self-evaporation capacity of ethanol is limited, and the flow rate typically drops below a set flow rate after a period of use (relevant studies show that an ethanol concentration affects an evaporation mode and rate of droplets on a superhydrophobic surface. At a low ethanol concentration (≤20 wt %), droplet evaporation is relatively slow and tends to a constant contact angle (CCA) mode, while at a high ethanol concentration (40 wt %-60 wt %), droplet evaporation is faster and tends to a constant contact radius (CCR) mode. As ethanol evaporates, the concentration gradually decreases, such that the evaporation mode may shift from CCR to CCA, thereby reducing an evaporation rate); second, the flow meter generates significant pipeline resistance, and an ethanol evaporation rate is increased by heating, because the flow meter's inherent pipeline resistance still causes failure to achieve high-flow supply, that is, requirements for both the high flow rate and high precision cannot be satisfied simultaneously, while a gaseous source flow rate affects the deposited film effect; and referring to FIG. 2, three images from left to right in FIG. 2 are scanning electron microscope (SEM) images of single-walled carbon nanotubes grown at gas flow rates of 100 sccm, 500 sccm, and 800 sccm, respectively, and when other conditions remain unchanged, as the gas flow rate increases, the number of grown carbon nanotubes increases significantly under the same SEM scale.

From the above description of the prior art carbon source supply method, gaseous source supply methods in the prior art fail to achieve high-flow supply; and therefore, in the present disclosure, the conventional method of flow control with a flow meter is abandoned, a solution of pressure control rather than flow control is innovatively provided, and a method for calibrating the pressure-flow rate relationship is further provided, such that more stable and precise gas pressure control is achieved though coupled atomization and heating control, thereby achieving high-flow, highly stable, and high-precision gas supply at a flow rate.

The high-flow supply solution provided in the present disclosure is also applicable to supply of other liquid sources such as methanol and phenol.

### Embodiment 1

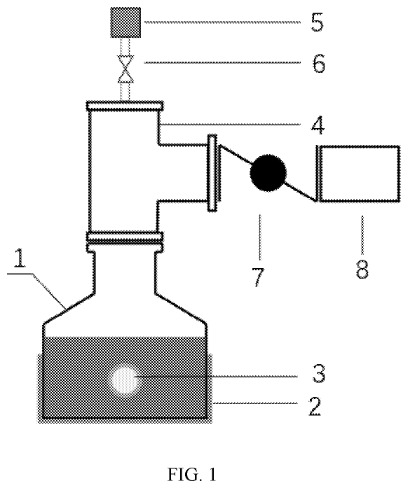

In the present embodiment, a high-flow gas generator for chemical vapor deposition equipment is provided, and referring to FIG. 1, the high-flow gas generator includes a source bottle 1, a heating device 2 is disposed outside the source bottle 1, an atomizer 3 is disposed in the source bottle 1, an outlet of the source bottle 1 is connected to a pressure gauge 5 via a three-way valve 4, an angle valve 6 is connected between the pressure gauge 5 and the three-way valve 4, and another port of the three-way valve 4 is connected to a gas supply pipeline 8 via a butterfly valve 7; and the gas supply pipeline 8 is connected to a film deposition chamber.

When the high-flow gas generator provides a carbon source for chemical vapor deposition equipment, both the angle valve 6 and the butterfly valve 7 are open, so pressure in the source bottle 1 is the same as pressure in the gas supply pipeline 8 and pressure in the film deposition chamber, that is, pressure displayed by the pressure gauge 5 is equal to the pressure in the source bottle 1 and also the pressure in the film deposition chamber.

The high-flow gas generator is applicable to gaseous sources in the liquid state, such as ethanol, methanol, phenol, and the like. A control process of the high-flow gas generator is described below by taking an example where the deposition equipment is a tube furnace, the high-flow gas generator provides an ethanol carbon source, and the gas supply pipeline 8 of the high-flow gas generator is connected to a quartz tube chamber in the tube furnace (in consideration of industry expression habits, the pressure in the tube furnace mentioned hereinafter refers to the pressure in the quartz tube chamber), where the gas supply pipeline 8 may be a bellows, the heating device 2 may be a heating jacket, and high-flow supply for the chemical vapor deposition process is achieved based on the high-flow gas generator, specifically including the following steps:
S1: calibrate a flow rate-pressure relationship; and
S1.1: place a gaseous source in a liquid state into the source bottle 1, adjust power of the heating device 2 and the atomizer 3 to stabilize gas pressure in the source bottle 1 at A₁ kPa, evacuate the gas pressure in the tube furnace to vacuum, open the butterfly valve 7 to supply gas to the tube furnace at a certain flow rate for N time, and measure the gas pressure in the tube furnace, where the gas pressure is denoted as B₁. A₁ typically ranges from 1 kPa to 3 kPa. The gaseous source in a liquid state includes ethanol, methanol, phenol, and the like.
S1.2: calibrate the gas pressure B₂ in the tube furnace after supplying a calibration gas at a flow rate of Q_{calibration} for N time via a mass flow meter; and
in the present embodiment, the calibration gas is Ar/H₂ gas, a H₂ volume ratio is 3%, and for calculation convenience, the gas pressure B₂ in the tube furnace is calibrated via the mass flow meter after supplying the Ar/H₂ gas at a flow rate of 1000 sccm.
S1.3: calculate an actual flow rate Q1 corresponding to gas supply to the tube furnace for N time when the gas pressure in the source bottle is stabilized at A₁ kPa via the following flow rate conversion formula:

$$Q 1 = \frac{{B}_{1}}{{B}_{2}} \times \frac{{C}_{calibration}}{{C}_{gaseous source}} \times {Q}_{calibration}$$

where Q_{calibration} is a gas flow rate of the calibration gas and known; C_{gaseous source} is a mass flow conversion coefficient of the gaseous source existing in a liquid state stored in the source bottle 1; and C_{calibration} is a mass flow conversion coefficient of the calibration gas.

A mass flow conversion coefficient of a substance may typically be obtained by consulting relevant technical manuals or calculated via a conversion coefficient calculation formula; and a basic conversion coefficient calculation formula is as follows:

$$C = \frac{0.3106 \times N}{ρ \times Cp}$$

where ρ is a density of the gas under standard conditions, Cp is constant-pressure specific heat of the gas, and N is a molecular composition coefficient of the gas, which is related to molecular composition of the gas.

If the calibration gas is a mixed gas, the conversion coefficient calculation formula is as follows:

$$C = \frac{\begin{matrix}0.31 06 \times [ N 1 \times ( ω 1 / ω T ) + N 2 \times \\ ( ω 2 / ω T ) + … + N n \times ( ω n / ω T ) ]\end{matrix}}{\begin{matrix}ρ1 \times C p 1 \times ( ω 1 / ω T ) + ρ2 \times Cp 2 \times \\ ( ω 2 / ω T ) + … + ρ n \times Cpn \times ( ω n / ω T )\end{matrix}}$$

where ρ1, ρ2, . . . , and ρn are densities of each gas in the mixed gas under standard conditions, Cp1, Cp2, . . . , and Cpn are constant-pressure specific heats of each gas in the mixed gas, and N1, N2, . . . , and Nn are gas molecular composition coefficients of each gas in the mixed gas; ω1, ω2, . . . , and ωn are flow rates of each gas in the mixed gas (determined based on proportions of each gas and a total flow rate), and ωT is a total flow rate of the mixed gas. For the present embodiment where ethanol serves as the carbon source and Ar/H₂ serves as the calibration gas, the flow conversion calculation formula is as follows:

$$Q = \frac{{B}_{1}}{{B}_{2}} \times \frac{{C}_{Ar / H 2}}{c} \times {Q}_{Ar / H 2}$$

where C_{Ar/H2} is a mass flow conversion coefficient of Ar/H₂, C is a mass flow conversion coefficient of ethanol, and for calculation convenience, Q_{Ar/H2} in the present embodiment is 1000 sccm, and other values may be selected in practical applications.

In practical application scenarios, the calibration gas in the S1.2 may be another gas, and the corresponding mass flow conversion coefficient C_{Ar/H2} is the mass flow conversion coefficient of the another gas. Generally, a gas with a known mass flow conversion coefficient is selected as the calibration gas.
S1.4: repeat the above S1.1 to S1.3 to obtain an actual flow rate Q2, A₂≠A₁ corresponding to gas supply to the tube furnace for N time when the gas pressure in the source bottle is stabilized at A₂ kPa.
S1.5: fit and determine parameters α and β in an expression of relationship between gas pressure P in the source bottle and a flow rate Q according to the actual flow rates Q1 and Q2 corresponding to the gas pressures A₁ and A₂ obtained in the S1.3 and the S1.4:

Q=α×P+β
where P represents gas pressure in the source bottle, and Q is a gas flow rate corresponding to the gas pressure P in the source bottle.

It should be noted that for setting the expression of relationship between the gas pressure P in the source bottle and the flow rate Q, since a deposition temperature is constant during the same deposition process, it is first assumed that the gas pressure P and the flow rate Q have a first-order linear relationship, and then the first-order linear relationship therebetween is verified through a large amount of experimental data; and therefore, the expression of relationship therebetween is assumed to be Q=α×P+β, and the parameters α and β α are then determined based on two sets of specific data.
S2: control pressure; and
according to the flow rate-pressure relationship calibrated in the S1, flow control is achieved by pressure control, and the second major advantage of the generator lies in that stable and precise flow control is achieved, i.e., stable and precise pressure control is achieved. the method is as follows:

In the present disclosure, closed-loop control is performed, the pressure gauge is used to monitor the gas pressure P in the source bottle in real time, and the pressure in the source bottle is regulated by adjusting the atomizer and controlling temperature of the generator. When target pressure is greater than current pressure, a PID controller correspondingly reduces power of the atomizer and temperature of the generator; and conversely, when the target pressure is less than the current pressure, the PID controller correspondingly increases the power of the atomizer and the temperature of the generator. The closed-loop control process may be achieved based on a PID control theory of the prior art, and the gas pressure P in the source bottle is maintained at a preset value by adjusting the power of the atomizer and the power of the heating device.

Specific control parameters of the PID controller are optimized by relevant technicians through experiments and adjustments according to actual dynamic characteristics and control objectives, and the specific adjustment process is not described in the present embodiment.

The present disclosure further provides a formula for controlling liquid-vapor conversion efficiency by coupling temperature and vibration power, and in the solution of the present disclosure, the heating device is a heating jacket capable of temperature display with a corresponding target temperature directly set, and the heating device automatically adjusts power to reach the corresponding target temperature. Therefore, temperature is directly used as one of control variables in the solution of the present disclosure.

Temperature control and atomization control have different effects on liquid-vapor conversion efficiencies, so reasonable control of temperature and the atomizer's power is required for effective and rapid temperature control. Assuming that current temperature of the generator is T_{current} and vaporization temperature of liquid in the source bottle is T_{vaporization}, current power of the heating device may be approximately simplified as:

W_{heating}=T_{current}/2T_{vaporization}

Assuming that current power of the atomizer is W_{atomization}, current power of the overall generator may be approximately expressed as:

W=K₁*W_{heating}+K₂*W_{atomization}

W_{heating}:W_{atomization}=K₁:K₂
where K₁ and K₂ are power weight coefficients of the heating device and the atomizer, respectively. Corresponding pressure may obtained by adjusting the power W of the overall generator.

In the film deposition process, after the gas generator is connected to a corresponding system (in a film deposition scenario, the corresponding system refers to the tube furnace), the heating device is used to heat the source bottle to temperature T₁ (T₁>T_{vaporization}), and power of the atomizer is adjusted to half of maximum power, and denoted as W_{atomization1}. Gas pressure P₁ displayed by the pressure gauge is observed after gas pressure of the gas generator (i.e., the gas pressure in the source bottle) is stabilized, the heating device is adjusted to heat the source bottle to temperature T₂ (T₂≤2T_{vaporization}) while keeping the power of the atomizer unchanged, and gas pressure displayed by the pressure gauge is observed as P₂; heating temperature is adjusted back to the temperature T₁, the power of the atomizer is adjusted to W_{atomization2}, and the pressure displayed by the pressure gauge is observed as P₃; accordingly:

$$\frac{{K}_{1}}{{K}_{2}} = \frac{( {P}_{2} - {P}_{1} ) * {T}_{1} * ( {W}_{a t o m i z a t i o n 2} - {W}_{a t o m i z a t i o n 1} )}{( {T}_{2} - {T}_{1} ) * ( {P}_{3} - {P}_{1} ) * {W}_{a t o m i z a t i o n 1}}$$

that is,

$${K}_{1} = \frac{\frac{( {P}_{2} - {P}_{1} ) * {T}_{1} * ( {W}_{atomization 2} - {W}_{atomization 1} )}{( {T}_{2} - {T}_{1} ) * ( {P}_{3} - {P}_{1} ) * {W}_{atomization 1}}}{( 1 + \frac{( {P}_{2} - {P}_{1} ) * {T}_{1} ( {W}_{atomization 2} - {W}_{atomization 1} )}{( {T}_{2} - {T}_{1} ) * ( {P}_{3} - {P}_{1} ) * {W}_{atomization 1}} )}$$

$${K}_{2} = \frac{1}{( 1 + \frac{( {P}_{2} - {P}_{1} ) * {T}_{1} * ( {W}_{a t o m i z a t i o n 2} - {W}_{a t o m i z a t i o n 1} )}{( {T}_{2} - {T}_{1} ) * ( {P}_{3} - {P}_{I} ) * {W}_{a t o m i z a t i o n 1}} )}$$

K₁ and K₂ are only applicable to temperatures and powers with high flow output.

### Embodiment 2

In the present embodiment, a specific film deposition case is provided: taking preparation of single-walled carbon nanotubes as an example, the high-flow gas generator provided in Embodiment 1 is used to supply a gaseous source to achieve large-area growth of single-walled carbon nanotubes, where ethanol serves as the gaseous source.

In the present embodiment, an argon-hydrogen mixture containing 3% hydrogen is used as the calibration gas for calibration, a mass flow conversion coefficient thereof is C_{Ar/H2}=1.40, and a mass flow conversion coefficient of ethanol is C=0.39. After the argon-hydrogen mixture is introduced at a flow rate of 1000 sccm for N=1 minute, pressure in the furnace is B₂=20.1 kPa. Pressure of the generator is controlled to A₁=20 kPa, after ethanol gas is introduced for 1 minute, the pressure in the furnace is B₁=14.2 kPa, and an ethanol flow rate corresponding to 20 kPa pressure is calculated according to the formula:

$$Q = \frac{{B}_{1}}{{B}_{2}} \times \frac{{C}_{Ar / H 2}}{C} \times {Q}_{Ar / H 2} = \frac{14.2}{20.1} \times \frac{1.4}{0.39} \times 1000 = 2536 sccm$$

The same method is used to measure the flow rate of 3524 sccm when the pressure of the generator is 30 kPa, and a fitted relationship between the pressure and the flow rate is:

Q=98.8P+560
where the unit of the flow rate is sccm and the unit of the pressure is kPa.

Corresponding K₁=0.62 and K₂=0.38 are calculated via the formula for controlling liquid-vapor conversion efficiency by coupling temperature and vibration power provided in Embodiment 1. When the pressure needs to be adjusted from 10 kPa to 15 kPa, the PLC adjusts the required power in real time via the PID algorithm. Assuming that current required power is 60%, power of the atomizer needs to be adjusted to 70.3% and power of the heating jacket needs to be adjusted to 43.1%, i.e., temperature of the heating jacket is adjusted to 67.5 °C.

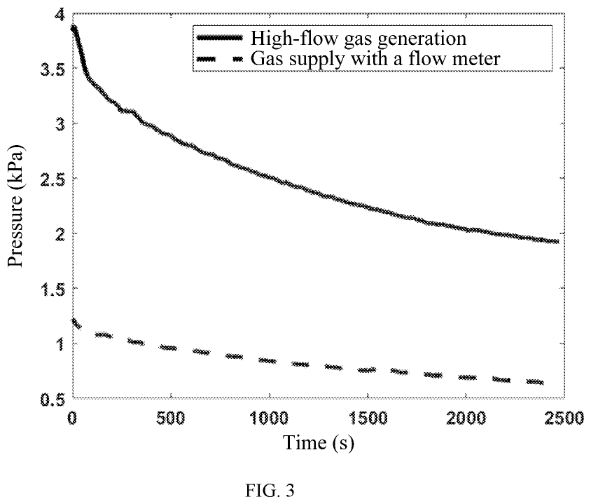

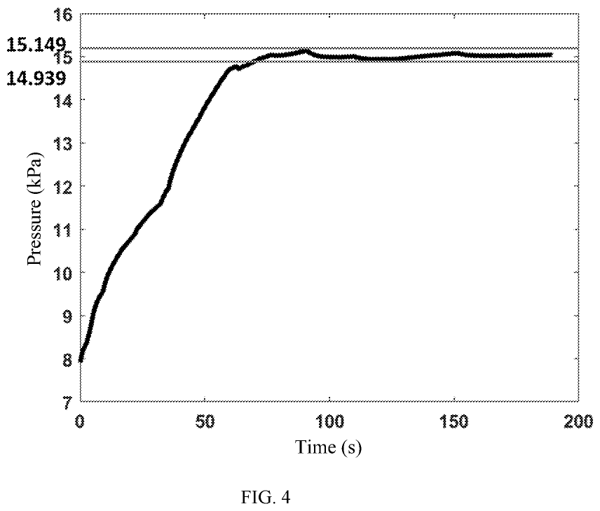

FIG. 3 is a flow rate comparison diagram of gas supply based on ethanol flow control through the conventional method of flow control with a flow meter and the high-flow gas generator provided in the present disclosure. It can be seen that corresponding pressure is higher when the high-flow gas generator provided in the present disclosure is used for ethanol flow control, that is, the high-flow gas generator provided in the present disclosure achieves high-flow ethanol gas supply. FIG. 4 shows a process of adjusting the gas pressure in the source bottle from 8 kPa to 15 kPa when a gaseous source is supplied by the high-flow gas generator provided in the present disclosure. It can be seen that the pressure may be adjusted to 15 kPa in approximately 70 s, a corresponding flow rate is 2042 sccm, and an error is stabilized within ±1%, indicating that the present disclosure is capable of achieving a stable flow rate.

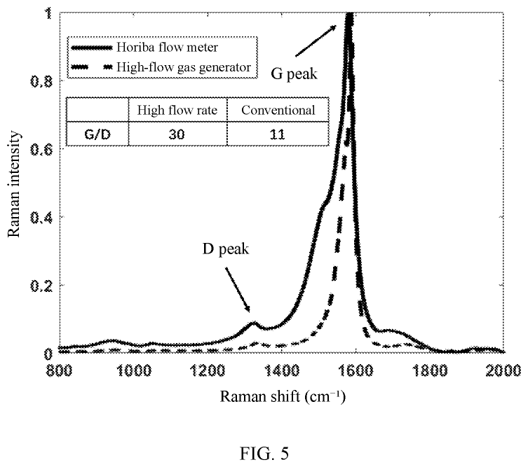

To further highlight excellent performance of the high-flow gas generator provided in the present disclosure in chemical vapor deposition scenarios, the present embodiment further compares results of supply a carbon source for growth of single-walled carbon nanotubes by using a prior art advanced flow controller (a Horiba flow meter) with a flow rate of 2000 sccm and the high-flow gas generator provided in the present disclosure. FIG. 5 shows a Raman spectrum of corresponding grown single-walled carbon nanotubes, and it can be seen that a G/D ratio (a ratio of G-peak intensity to D-peak intensity) of single-walled carbon nanotubes corresponding to carbon source supply by the high-flow gas generator provided in the present disclosure is 30 in the Raman spectrum, while a G/D ratio corresponding to carbon source supply by the prior art Horiba flow meter is only 11. A high G/D ratio generally indicates that the material has better crystallinity and fewer lattice defects, that is, carbon source supply by the high-flow gas generator provided in the present disclosure improves the quality of grown single-walled carbon nanotubes.

Some steps in the embodiments of the present disclosure may be implemented by software, and corresponding software programs may be stored in a readable storage medium such as an optical disk or a hard disk drive.

The foregoing descriptions are merely preferred embodiments of the present disclosure, but are not intended to limit the present disclosure. Any modifications, equivalent replacements, or improvements made within the spirit and principle of the present disclosure shall all fall within the protection scope of the present disclosure.

What is claimed is:

1. A high-flow gas supply method for chemical vapor deposition equipment, wherein the method is implemented based on a high-flow gas generator, and the high-flow gas generator comprises: a source bottle, a heating device, an atomizer, a pressure gauge, and a controller; the source bottle is configured to store a gaseous source existing in a liquid state, the heating device and the atomizer are configured to convert the gaseous source in the source bottle from the liquid state to a gaseous state, and the controller is configured to adjust power of the heating device and the atomizer according to a required flow rate to adjust gas pressure in the source bottle;
wherein in the high-flow gas generator, the heating device is disposed outside the source bottle, the atomizer is disposed in the source bottle, an outlet of the source bottle is connected to the pressure gauge via a three-way valve, an angle valve is connected between the pressure gauge and the three-way valve, another port of the three-way valve is connected to a gas supply pipeline via a butterfly valve, and the gas supply pipeline is connected to a chemical vapor deposition chamber; the heating device, the atomizer, and the pressure gauge are all connected to the controller; the method comprises:
S1: calibrating a relationship between pressure in the source bottle and a flow rate for the gaseous source existing in a liquid state in the source bottle;
S2: determining target pressure in the source bottle according to a required flow rate, and using a PID algorithm to control power of the heating device and the atomizer to stabilize pressure in the source bottle at the target pressure;
wherein the S1 comprises:
S1.1: placing the gaseous source existing in a liquid state into the source bottle, adjusting power of the heating device and the atomizer to stabilize gas pressure in the source bottle at A₁ kPa, evacuating the chemical vapor deposition chamber to vacuum, opening the butterfly valve to supply gas to the chemical vapor deposition chamber at a certain flow rate for N time, and measuring the gas pressure in the chemical vapor deposition chamber, wherein the gas pressure is denoted as B₁;
S1.2: calibrating gas pressure B₂ in the chemical vapor deposition chamber after supplying a calibration gas at a flow rate of Q_{calibration} for N time via a mass flow meter; and
S1.3: calculating an actual flow rate Q1 corresponding to gas supply to the chemical vapor deposition chamber for N time when the gas pressure in the source bottle is stabilized at A₁ kPa via the following flow rate conversion formula:
$$Q 1 = \frac{{B}_{1}}{{B}_{2}} \times \frac{{C}_{Calibration}}{{C}_{Gaseous source}} \times {Q}_{Calibration}$$
in the formula, Q_{calibration} is a gas flow rate of the calibration gas and known; C_{gaseous source} is a mass flow conversion coefficient of the gaseous source existing in a liquid state stored in the source bottle; and C_{calibration} is a mass flow conversion coefficient of the calibration gas;
S1.4: repeating the above S1.1 to S1.3 to obtain an actual flow rate Q2 corresponding to gas supply to the chemical vapor deposition chamber for N time when the gas pressure in the source bottle is stabilized at A₂ kPa, A₂≠A₁;
S1.5: fitting and determining parameters α and β in an expression of relationship between gas pressure P in the source bottle and a flow rate Q according to the actual flow rates Q1 and Q2 corresponding to the gas pressures A₁ and A₂ obtained in the S1.3 and the S1.4:
Q=α×P+β
in the expression, P represents gas pressure in the source bottle, and Q is a gas flow rate corresponding to the gas pressure P in the source bottle;
the method further comprises before using a PID algorithm to control power of the heating device and the atomizer to stabilize pressure in the source bottle at the target pressure in the S2: determining a relationship between liquid-vapor conversion efficiency and coupling of temperature provided by the heating device and vibration power of the atomizer:
wherein current power of the heating device is defined as follows: W_{heating}=T_{current}/2T_{vaporization}, wherein T_{current} represents current temperature of the generator, and T_{vaporization} represents vaporization temperature of liquid in the source bottle;
wherein power of the atomizer is defined as W_{atomization}, and current power of the entire generator is denoted as: W=K₁*W_{heating}+K₂*W_{atomization}, wherein K₁ and K₂ are power weight coefficients of the heating device and the atomizer, respectively, and corresponding pressure is obtained by adjusting the power W of the entire generator;
wherein the power weight coefficients K₁ and K₂ of the heating device and the atomizer are determined by the following method:
heating the source bottle to temperature T₁ by using the heating device, wherein T₁>T_{vaporization}, and adjusting the power of the atomizer to half of maximum power, with the power denoted as W_{atomization1}; observing current gas pressure P₁ displayed by the pressure gauge after the gas pressure in the source bottle is stabilized;
heating the source bottle to temperature T₂ by adjusting the heating device while keeping the power of the atomizer unchanged, wherein T₂≤2T_{vaporization}, and observing gas pressure displayed by the pressure gauge as P₂;
adjusting heating temperature back to T₁, adjusting the power of the atomizer to W_{atomization2}, wherein W_{atomization2}≠W_{atomization1}, and observing gas pressure displayed by the pressure gauge as P₃,
K₁ and K₂ are respectively:
$${K}_{1} = \frac{\frac{( {P}_{2} - {P}_{1} ) * {T}_{1} * ( {W}_{atomization 2} - {W}_{atomization 1} )}{( {T}_{2} - {T}_{1} ) * ( {P}_{3} - {P}_{1} ) * {W}_{atomization 1}}}{( 1 + \frac{( {P}_{2} - {P}_{1} ) * {T}_{1} ( {W}_{atomization 2} - {W}_{atomization 1} )}{( {T}_{2} - {T}_{1} ) * ( {P}_{3} - {P}_{1} ) * {W}_{atomization 1}} )}$$
$${K}_{2} = \frac{1}{( 1 + \frac{( {P}_{2} - {P}_{1} ) * {T}_{1} * ( {W}_{a t o m i z a t i o n 2} - {W}_{a t o m i z a t i o n 1} )}{( {T}_{2} - {T}_{1} ) * ( {P}_{3} - {P}_{I} ) * {W}_{a t o m i z a t i o n 1}} )}$$
the heating device is a heating jacket capable of temperature display, and power is automatically adjusted by adjusting temperature.

2. The high-flow gas supply method according to claim 1, wherein the calibration gas in the S1.2 is an Ar/H₂ gas.

3. The high-flow gas supply method according to claim 2, wherein A₁ ranges from 1 kPa to 3 kPa.

4. The high-flow gas supply method according to claim 3, wherein the gaseous source in a liquid state comprises ethanol, methanol, and phenol.

5. A high-flow gas generator for chemical vapor deposition equipment, wherein the high-flow gas generator comprises: a source bottle, a heating device, an atomizer, a pressure gauge, and a controller; the source bottle is configured to store a gaseous source existing in a liquid state, the heating device and the atomizer are configured to convert the gaseous source in the source bottle from the liquid state to a gaseous state, and the controller is configured to implement the method according to claim 1 and adjust power of the heating device and the atomizer according to a required flow rate to adjust gas pressure in the source bottle; and
in the high-flow gas generator, the heating device is disposed outside the source bottle, the atomizer is disposed in the source bottle, an outlet of the source bottle is connected to the pressure gauge via a three-way valve, an angle valve is connected between the pressure gauge and the three-way valve, another port of the three-way valve is connected to a gas supply pipeline via a butterfly valve, and the gas supply pipeline is connected to a chemical vapor deposition chamber; the heating device, the atomizer, and the pressure gauge are all connected to the controller.
